(19) United States
(12) Patent Application Publication
(10) Pub. No.: US 2005/0202611 A1
(43) Pub. Date: Sep. 15, 2005

(54) Method of laser irradiation

(76) Inventors: Hiroshi Mitsuhashi, Minato-ku (JP); Kiyotsugu Mizouchi, Minato-ku (JP); Takashi Awano, Minato-ku (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 11/054,555

(22) Filed: Feb. 10, 2005

Related U.S. Application Data
(63) Continuation of application No. PCT/JP03/10223, filed on Aug. 11, 2003.

(30) Foreign Application Priority Data
Aug. 13, 2002 (JP) 2002-236054

(51) Int. Cl. H01L 21/428

(52) U.S. Cl. 438/166; 438/487

(57) ABSTRACT

A method of laser irradiation including reflecting a linear laser beam from a mirror to bend an optical path of the laser beam, adjusting a width of the laser beam in the short axis direction of the laser beam whose optical path is bent by the mirror, by a short axis homogenizer, and irradiating an amorphous silicon semiconductor on a translucent substrate with the laser beam whose width in the short axis direction is adjusted by the short axis homogenizer, wherein the intensity of the laser beam is adjusted by adjusting the angle of the mirror.

### CROSS REFERENCE TO RELATED APPLICATIONS

This is a Continuation Application of PCT Application No. PCT/JP03/10223, filed Aug. 11, 2003, which was published under PCT Article 21(2) in Japanese.

This application is based upon and claims the benefit of priority from prior Japanese Patent Application No. 2002-236054, filed Aug. 13, 2002, the entire contents of which are incorporated herein by reference.

### BACKGROUND OF THE INVENTION

1. Field of the Invention

The present invention relates to a method of laser irradiation with which an amorphous silicon film on a translucent substrate is irradiated with laser beams.

2. Description of the Related Art

Liquid crystal displays (LCD) are now used which use, as a pixel switch, an insulated gate type thin film transistor (TFT) formed of amorphous silicon (a-Si). However, a thin film transistor using amorphous silicon, which has a low electric field mobility (μFE) of at most 1 cm²/Vs, has capabilities insufficient to implement a liquid crystal display having a high definition, operating at high speed, and providing excellent functions.

In contrast, a thin film transistor using polycrystal silicon and produced by a laser anneal process of irradiating an amorphous silicon layer with excimer laser beams has an electric field mobility of about 100 cm²/Vs to 200 cm²/Vs. Thus, this thin film transistor is expected to provide high functions such as the capability of increasing the definition and operating speed of a liquid crystal display and the capability of allowing the integral formation of a drive circuit.

The laser anneal process is a method of irradiating an amorphous silicon layer on a glass substrate that is a translucent substrate, with excimer laser beams. Specifically, the amorphous silicon layer on the glass substrate is formed into a polysilicon layer by properly setting the beam size on the surface of the amorphous silicon layer, for example, setting the length of each beam at 250 mm and its width at 0.4 mm, oscillating the pulse beam at 300 Hz, and gradually shifting an irradiated area for each pulse.

Furthermore, an element that determines the electric field mobility of the thin film transistor using the polysilicon layer is the grain size of polysilicon. This depends greatly on the energy density of applied laser beams, what is called fluence. Specifically, the grain size of polysilicon increases consistently with the fluence. However, a fluence higher than a value F1 is required to obtain high-performance polysilicon of electric field mobility at least 100 cm²/Vs.

However, as the fluence increases above F1, the grain size of polysilicon further increases, but the polysilicon becomes microcrystal grains at a certain fluence value, that is, F2. Such microcrystal polysilicon does not provide desired transistor characteristics. The area between F1 and F2 is called a fluence margin.

The grain size of polysilicon can be determined by etching the polysilicon layer with an etchant and using a scanning electron micrograph (FE-SEM) to observe the grain size. This method is used to select the fluence of the laser beams from an area in which the polysilicon has a somewhat larger grain size, that is, the area between F1 and F2. This selection enables a thin film transistor made of polysilicon and having the desired electric field density to be obtained regardless of a certain amount of variations in the oscillation intensity of the laser beam.

However, the fluence margin, which is the above described range between F1 and F2, is very small. Changes in laser beams are likely to cause the fluence to deviate from the area between F1 and F2. This disadvantageously affects the mass production of thin film transistors made of polysilicon. Furthermore, the fluence margin depends on the number of pulse irradiations of laser beams. About 10 times of pulse irradiations provide only a very small fluence margin. About 20 times of pulse irradiations barely provide a fluence margin sufficient for production. Thus, it is disadvantageously difficult to adjust the intensity of the laser beams.

The present invention is provided in view of this. It is an object of the present invention to provide a method of laser irradiation which enables the intensity of laser beams to be properly adjusted all over the surface of the translucent substrate.

### BRIEF SUMMARY OF THE INVENTION

According to the present invention, there is provided a method of laser irradiation comprising reflecting a linear laser beam from a mirror to bend an optical path of the laser beam; adjusting a width of the laser beam in the short axis direction of the laser beam whose optical path is bent by the mirror, by a short axis homogenizer; and irradiating an amorphous silicon semiconductor on a translucent substrate with the laser beam whose width in the short axis direction is adjusted by the short axis homogenizer, wherein the intensity of the laser beam is adjusted by adjusting the angle of the mirror.

With the method of laser irradiation according to the present invention, the angle of the mirror is adjusted so that the short axis homogenizer can adjust the short axis-wise width of each laser beam. Then, the amorphous silicon semiconductor on the translucent substrate is irradiated with the laser beams each having its short axis-wise width adjusted. The intensity of each laser beam can be adjusted simply by adjusting the angle of the mirror. This makes it possible to properly adjust the intensity of the laser beam all over the surface of the translucent substrate.

### BRIEF DESCRIPTION OF THE SEVERAL VIEWS OF THE DRAWING

FIG. 1 is a view illustrating a laser anneal apparatus according to an embodiment of the present invention.

FIG. 2 is a sectional view showing a liquid crystal display device manufactured using the laser anneal apparatus shown in FIG. 1.

FIG. 3 is a view illustrating optical paths through short axis homogenizers of the laser anneal apparatus shown in FIG. 1.

FIG. 4 is a view illustrating optical paths through conventional short axis homogenizers.

FIG. 5 is a view illustrating how leakage light occurs in the conventional short axis homogenizers.

### DETAILED DESCRIPTION OF THE INVENTION

With reference to the drawings, description will be given of a method of laser irradiation according to an embodiment of the present invention.

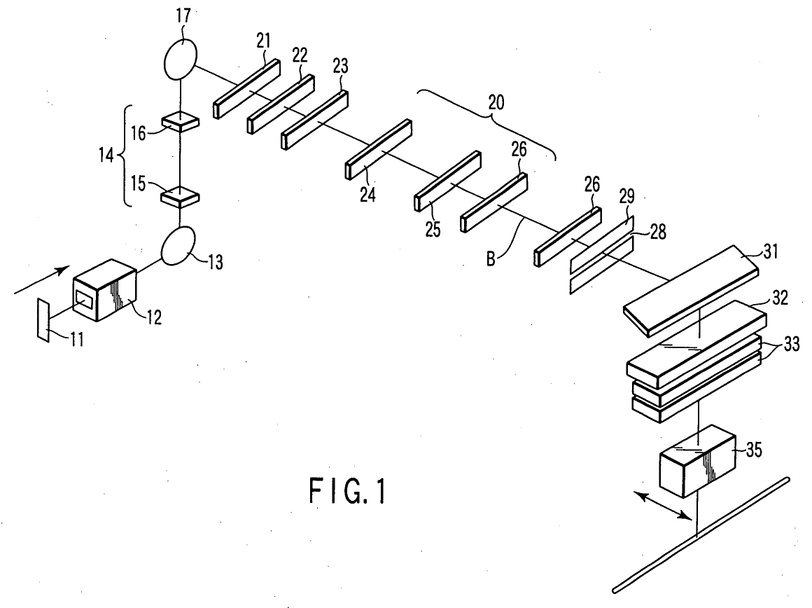

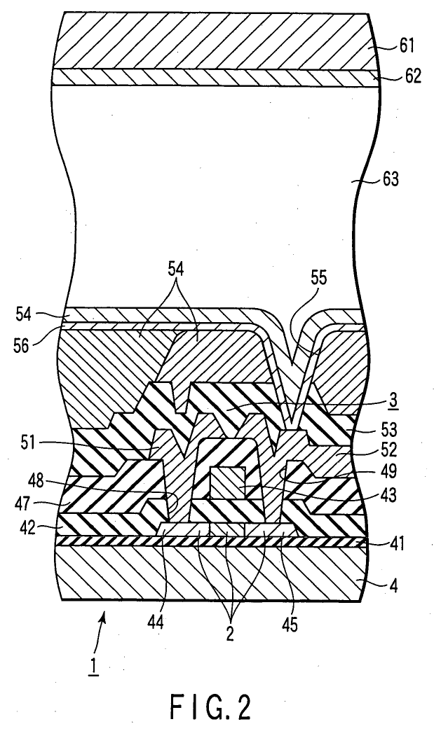

A laser anneal apparatus as a laser irradiation apparatus, shown in FIG. 1, is a part of an apparatus that manufactures a liquid crystal display (LCD) based on an active matrix system, shown in FIG. 2. The liquid crystal display shown in FIG. 2 comprises a insulated gate type thin film transistor (TFT) 3. The thin film transistor 3 is used as a pixel switch for the liquid crystal display and is formed by a polysilicon layer 2 on an array substrate 1.

The laser anneal apparatus shown in FIG. 1 irradiates a thin film of amorphous silicon with generally rectangular excimer laser beams B as linear beams emitted by a pulse laser such as xenon chloride (XeCl) laser, the thin film being formed on one major surface of a glass substrate 4 as a translucent substrate, shown in FIG. 2.

Then, the amorphous silicon layer located all over the surface of the glass substrate 4 is subjected to laser annealing to convert to the polysilicon layer 2.

Furthermore, the laser anneal apparatus shown in FIG. 1 comprises a laser oscillator 11 that is laser oscillating means oscillating the excimer laser beams B. The excimer laser beams B oscillated by the laser oscillator 11 become linear shape on the surface of the amorphous silicon layer on the glass substrate 4. The excimer laser beams B oscillated by the laser oscillator 11 are adjusted to consequently focus on the glass substrate 4.

Moreover, a variable attenuator 12 that is a light attenuator is located ahead of laser oscillator 11 in the optical paths of the excimer laser beams B oscillated by the laser oscillator 11. The variable attenuator 12 is of a voltage variable type and varies the transmittance of the excimer laser beams 3. A first mirror 13 as a total reflection mirror is disposed ahead of the variable attenuator 12 in the optical paths of the excimer laser beams B having passed through the variable attenuator 12. The first mirror 13 totally reflects the excimer laser beams B to bend their optical paths to change irradiated positions.

The first mirror 13 is installed so as to be pivotable along a plane containing the optical axes of the excimer laser beams B oscillated by the laser oscillator 11. Moreover, a micro actuator (not shown) is installed at the first mirror 13 to remotely control the angles of the incident excimer laser beams B.

A plurality of telescope lenses, for example, one first telescope lens 1 and one second telescope lens 16 are coaxially disposed ahead of the first mirror 13 in the optical paths of the excimer laser beams B totally reflected by the first mirror 13. The first telescope lens 15 and the second telescope lens 16 adjust the excimer laser beams B to parallel light.

A second mirror 17 is disposed ahead of the second telescope lens 16 in the optical paths of the excimer laser beams B having passed through the second telescope lens 16. The second mirror 17 totally reflects the excimer laser beams B to bend their optical paths to change the irradiated positions in a direction different from the direction of the irradiated positions established by the first mirror 13. The second mirror 17 is installed so as to be pivotable along a plane containing the optical axes of the excimer laser beams B having passed through the second telescope lens 16.

A first long axis homogenizer 21 and a second long axis homogenizer 22 as long axis homogenizers (LAH) are coaxially disposed ahead of the second mirror 17 in the optical paths of the excimer laser beams B totally reflected by the second mirror 17. The first and second long axis homogenizers 21 and 22 adjust the long axis-wise width of each excimer laser beam B and thus its intensity.

The pivot angle of the second mirror 17 is adjusted to provide each excimer laser beam B with the maximum intensity so that the first long axis homogenizer 21 and the second long axis homogenizer 22 can adjust the long axis-wise width of the excimer laser beam B through zooming, while setting the long axis-wise length of the excimer laser beam B at a predetermined value, or uniformly maximize the long axis-wise intensity of each excimer laser beam B.

Furthermore, a long axis condensing lens 23 as a condenser lens is disposed ahead of the second long axis homogenizer 22 in the optical paths of the excimer laser beams B having passed through the second long axis homogenizer 22. The long axis condensing lens 23 corrects the waveforms of the excimer laser beams B having their long axis-wise width adjusted and their long axis-wise intensity maximized by the first long axis homogenizer 21 and second long axis homogenizer 22. The long axis condensing lens 23 finely adjusts the focal distances of the excimer laser beams B.

Moreover, a first short axis homogenizer 24 and a second short axis homogenizer 25 as a cylindrical lens array are coaxially disposed ahead of the long axis condensing lens 23 in the optical paths of the excimer laser beams B having passed through the long axis condensing lens 23; the first short axis homogenizer 24 and the second short axis homogenizer 25 are short axis homogenizers (SAH) that adjust the short axes of the excimer laser beams B. The second short axis homogenizer 25 is located on the optical axis of the first short axis homogenizer 24 near the focus of the first short axis homogenizer 24. The first short axis homogenizer 24 and the second short axis homogenizer 25 constitute a short axis homogenizer 20.

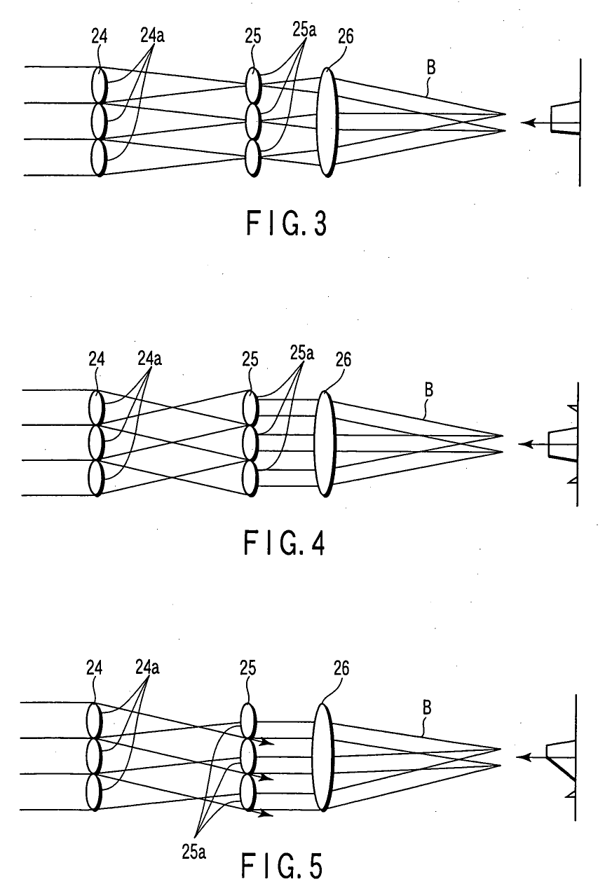

Here, the first short axis homogenizer 24 comprises first segment lenses 24a that are a plurality of convex lenses, as an array lens, as shown in FIG. 3. Each of the first segment lenses 24a has a segment with radius of curvature r of 219. Furthermore, the first segment lens 24a has a focal distance f of 438 and causes the beams to have a diameter of 0.1 mm on the second segment lens 25a. The first segment lenses 24a are arranged on the same plane in parallel so that their lens optical axes are parallel with one another.

Moreover, the second short axis homogenizer 25 comprises a second segment lenses 25a that are a plurality of convex lenses. Each of the second segment lenses 25a is disposed on the optical path of the corresponding first segment lens 24a. The second segment lenses 25a are arranged on the same plane in parallel so that their lens optical axes are parallel with one another. Furthermore, each of the second segment lenses 25a has its optical axis coincide with that of the corresponding first segment lens 24a. Moreover, the second segment lens 25a has the same radius of curvature as that of the corresponding first segment lens 24a. The span between the first segment lens 24a and the corresponding second segment lens 25a is 460 mm.

The pivot angle of the first mirror 13 is adjusted so as to set the intensity of each excimer laser beam B to the appropriate or maximum value so that the first short axis homogenizer 24 and the second short axis homogenizer 25 can adjust the short axis-wise width of the excimer laser beam B through zooming, while setting the short axis-wise length of the excimer laser beam B to a predetermined value, or uniformly maximize the short axis-wise intensity of each excimer laser beam B.

A short axis condensing lens 26 as a condenser lens is disposed ahead of the second short axis homogenizer 25 in the optical paths of the excimer laser beams B having passed through the second short axis homogenizer 25. The short axis condensing lens 26 corrects the waveforms of the excimer laser beams B having their long axis-wise width adjusted and their long axis-wise intensity maximized by the first short axis homogenizer 24 and second short axis homogenizer 25. The short axis condensing lens 26 finely adjusts the focal distances of the excimer laser beams B.

A field lens 27 is disposed ahead of the short axis condensing lens 26 in the optical axes of the excimer laser beams B having passed the short axis condensing lens 26. The field lens 26 adjusts the focal depths of the excimer laser beams B. Furthermore, a focus slit 29 is disposed ahead of the field lens 27 in the optical paths of the excimer laser beams B having passed through the field lens 27. The focus slit 29 acts as a focus checking gap having a gap 28 used to check the focus.

Moreover, a third mirror 31 is disposed ahead of the focus slit 29 in the optical paths of the excimer laser beams B having passed through the focus slit 29. The third mirror 31 bend the excimer laser beams B by, for example, totally reflecting them at 90°. Furthermore, an image surface curvature correcting lens 32 is disposed ahead of the third mirror 31 in the optical paths of the excimer laser beams B having passed through the third mirror 31. The image surface curvature correcting lens 32 corrects the curved surface of the image formed by the excimer laser beams. Moreover, a projection lens 33, what is called a 5× reduction lens, is disposed ahead of the image surface curvature correcting lens 32 in the optical paths of the excimer laser beams B having passed through the image surface curvature correcting leans 32. The projection lens 33 reduces the beam width of each excimer laser beams B down to, for example, one-fifth.

The glass substrate 4 is installed ahead of the projection lens 33 in the optical paths of the excimer laser beams B having passed through the projection lens 33. The glass substrate 4 is installed so that the amorphous silicon layer on the glass substrate 4 is directed toward the optical paths of the excimer laser beams B.

On the other hand, a beam profiler 35 is mounted on the laser anneal apparatus as an inspecting device that measures the shapes of the excimer laser beams B on the glass substrate 4. The beam profiler 35 is installed ahead of the projection lens 33 in the optical paths of the excimer laser beams B having passed through the projection lens 33. When the amorphous silicon on the glass substrate 4 is subjected to laser annealing, the beam profiler 35 stands by at a position where it does not cross the applied excimer laser beams B. Furthermore, the beam profiler 35 measures the beam shapes of the excimer laser beams B after the angle of the first mirror 13 has been adjusted, to detect the rotating angles of the first mirror 13 and second mirror 17 at which the excimer laser beams B have the maximum intensity in each of the long and short axis directions.

Here, the beam profiler 35 makes measurement when an inert gas in the beam profiler 35 is replaced with a fresh one, for example, once a day, more specifically after excimer laser beams B of 300-Hz pulses have been applied 2×10⁷ times, that is, every 18.5 hours.

Now, with reference to FIG. 2, description will be given of the configuration of a liquid crystal display manufactured using the laser irradiation apparatus.

The liquid crystal display comprises the array substrate 1. The array substrate 1 comprises the glass substrate, which is substantially transparent and has an insulating property. The glass substrate 4 has a size of, for example, 400 mm×500 mm. An undercoat layer 41 is formed on one major surface of the glass substrate 4 to prevent the diffusion of impurities from the glass substrate 4. The undercoat layer 41 is composed of SiNx and SiOx and formed by a plasma CVD process.

An island-like polysilicon layer 2 is formed on the undercoat layer 41. The polysilicon layer 2 is formed by irradiating the amorphous silicon layer deposited on the glass substrate 4, with the excimer laser beams B for laser annealing.

A gate oxide film 42 composed of, for example, a silicon oxide film having an insulating property is formed on the polysilicon layer 2 and undercoat layer 41. A gate electrode 43 composed of a molybdenum-tungsten alloy (MoW) is formed on the gate oxide film 42. The polysilicon layer 2, the gate oxide film 42, the gate electrode 43, and others form the thin film transistor 3.

Furthermore, a source region 44 and a drain region 45 in both of which impurities are doped are formed in the areas at the respective sides of the area of the polysilicon layer 2 located immediately below the gate electrode 43. The area of the polysilicon layer 2 located immediately below the gate electrode 43 is not doped but constitutes a channel region.

An interlayer insulating film 47 composed of a silicon oxide film or the like is formed on the gate oxide film 42 and gate electrode 43. First contact holes 48 and 49 are formed in the interlayer insulating film 47 and gate oxide film 42 so as to penetrate the interlayer insulating film 47 and gate oxide film 42. The contact holes 48 and 49 are formed in communication with a source region 44 and a drain region 45, respectively.

A source electrode 51, a drain electrode 52, and a signal line (not shown) for supplying signals are formed on the interlayer insulating film 47; the source electrode 51 and drain electrode 52 are formed as a second interconnect layer. The source electrode 51, the drain electrode 52, and the signal line are formed of, for example, a low-resistance metal such as aluminum (Al). The source electrode 51 is electrically connected to the source region 44 via the first contact hole 48. Similarly, the drain electrode 52 is electrically connected to the drain region 45 via the first contact hole 49.

A protective film 53 is formed on the interlayer insulating film 47, source electrode 51, and drain electrode 52. A color filter 54 in three colors, for example, red, blue, and green is formed on the protective film 53. A second contact hole 55 is formed in the protective film 53 and color filter 54 so as to be in contact with the drain electrode 52.

Pixel electrodes 56 that are a transparent conductor layer are disposed on the color filter 54 in a matrix. The pixel electrodes 56 are electrically connected to the source electrode 51 via the second contact hole 55. Furthermore, an orientation film 57 as a protective film is formed on the pixel electrodes 56.

An opposite substrate 61 is disposed opposite the pixel electrodes 56. An opposite electrode 62 is formed on one major surface of the opposite substrate 61 which is opposite the pixel electrodes 56. Moreover, a liquid crystal 63 is interposed between the pixel electrodes 56 on the array substrate 1 and the opposite electrode 62 on the opposite substrate 61.

Now, description will be given of a method of manufacturing a liquid crystal display using the laser irradiation apparatus.

First, a silicon oxide film or the like is formed on one major surface of the glass substrate 4 by the plasma CVD process to form the undercoat layer 41. Subsequently, an amorphous silicon layer of film thickness 50 nm is formed.

Then, the amorphous silicon layer is thermally treated in a nitrogen atmosphere at 500° C. for 10 minutes to reduce the concentration of hydrogen in the amorphous silicon layer. On this occasion, the amorphous silicon layer is measured by a spectral ellipsometric process to have a film thickness of 49.5 nm.

Subsequently, the glass substrate 4 is transferred to the laser anneal apparatus.

Then, the angle of the first mirror 13 is adjusted so as to maximize the short axis-wise intensity of each excimer laser beam B. Furthermore, the transmittance of the variable attenuator 12 is set at 85%.

In this state, the glass substrate 4 with the concentration of hydrogen in the amorphous silicon layer reduced is installed on a stage (not shown). The stage is moved parallel with the short axes of the beams at a pitch of 20 μm, while irradiating the amorphous silicon layer on the glass substrate 4 with the excimer laser beams B having a short axis of width about 400 μm. The amorphous silicon layer is thus subjected to laser annealing to convert to the polysilicon layer 2 with the desired crystal grain size. On this occasion, each point on the glass plate 4 is irradiated with a laser pulse 20 times.

Then, the excimer laser beams B oscillated by the laser oscillator 11 at 300 Hz are set to be linear and to have an irradiation size of 250 mm×0.4 mm. The glass substrate 4 is moved at 6 mm/s. As a result, every time one shot of the excimer laser beams B is applied, the glass substrate 4 is moved at a pitch of 20 μm.

Then, the polysilicon layer 2 is patterned. Thereafter, the gate oxide film 42 is formed by the plasma CVD process or the like on the glass substrate 4 including the polysilicon layer 2.

Then, a first interconnect layer is formed on the gate oxide film 42 by a sputtering process. The first interconnect layer is etched to form the gate electrode 43.

Subsequently, a photolithography technique is used to form the source region 44 and the drain region 45 at the respective sides of the polysilicon layer 2. The thin film transistor 3 is thus produced. The source region 44 and the drain region 45 are formed by using resist used to etch the gate electrode 43, as a mask to dope impurities such as boron (B) or phosphorous (P) in the areas at the respective sides of the polysilicon layer 2 by an ion doping process or the like. At this time, the part of the polysilicon layer 3 located below the gate electrode 43 constitutes a channel region.

Then, the interlayer insulating film 47 is formed on the gate oxide film 42 and gate electrode 43. The first contact holes 48 and 49 are then formed in the interlayer insulating film 47 and gate oxide film 42. Subsequently, a layer of a low-resistance metal is formed on the interlayer insulating film 47 by the sputtering process or the like. The layer is then patterned to form the source electrode 51, the drain electrode 52, and the signal line.

Then, the protective film 53 is formed on the interlayer insulating film 47, source electrode 51, and drain electrode 52. Then, the color filter 54 is formed on the protective film 53.

Moreover, a transparent conductor layer such as ITO (Indium Tin Oxide) is formed on the color filter 54. Then, the transparent conductor layer is etched to form the pixel electrodes 56.

Subsequently, the opposite electrode 61 and the array substrate 1 are disposed opposite each other. The opposite electrode 62 is formed on one major surface of the opposite electrode 61 which is opposite the array substrate 1.

Then, the liquid crystal 63 is injected between the opposite substrate 61 and the array substrate 1 to complete a liquid crystal display.

As described above, according to the present embodiment, the laser anneal apparatus provides the excimer laser beams B of short axis-wise width about 400 μm, and the stage with the glass substrate 4 placed on it is moved parallel with the short axis direction of the excimer laser beams B at a pitch of 20 μm. Thus, each point of the glass substrate 4 is irradiated with the laser pulse of the excimer laser beam B 20 times.

In this case, in the prior art, the excimer laser beams B of short axis-wise width about 400 μm are optically adjusted at a laser oscillation frequency of a low pulse frequency of about 1 to 50 Hz, more preferably 25 Hz. That is, the laser oscillation frequency is reduced because conventional CCD profiler cameras that display an analysis chart formed through adjustment have a low loading speed and cannot follow a frequency of 300 Hz and because a display screen for the analysis chart has only a low refresh speed.

When the amorphous silicon layer on the substrate 4 is actually converted into the polysilicon layer 2, the excimer laser beams B have a laser oscillation frequency of 300 Hz, which is one order higher than that observed during the optical adjustment, that is, 1 to 50 Hz. At such a high frequency, the excimer laser beams B emitted by the laser oscillator 11 exhibit nature different from that exhibited at a low frequency. The beams have a larger spread angle at 300 Hz than at 50 Hz or less. Furthermore, the orientation of laser pulses at 300 Hz is different from that at 50 Hz or less.

Thus, in the prior art, the first short axis homogenizer 24 having a radius of curvature r of 170 is combined with the second short axis homogenizer 25 having a radius of curvature r of 219, with the span between the first short axis homogenizer 24 and the second short axis homogenizer 25 set at about 480 mm. Thus, the excimer laser beams B are shaped to have a short axis length of about 400 μm on the glass substrate 4.

Here, the focal distance f of the first short axis homogenizer 24 can be determined from 1/f=(n−1)/r. Since n is 1.5, the focal distance f is 2r. Accordingly, the first short axis homogenizer 24 has a focal distance f of 340, which corresponds to the vicinity of the center of the first and second short axis homogenizers 24 and 25. In this case, owing to their spread angle at 300 Hz, the excimer laser beams B have an increase beam diameter of up to about 1 mm at the position of the second short axis homogenizer 25.

Furthermore, the first segment lenses 24a of the first short axis homogenizer 24 and the second segment lenses 25a of the second short axis homogenizer 25 each have a width of 2 mm. As shown in FIG. 3, the first short axis homogenizer 24 and the second short axis homogenizer 25 are designed so that the excimer laser beams B divided and condensed by the segment lenses 24a of the first short axis homogenizer 24 are each incident on the center of the opposite second segment lens 25a of the second short axis homogenizer 25.

However, as shown in FIG. 5, with the excimer laser beams B at 300 Hz, a variation in beam orientation and an increase in beam spread angle are combined with each other to cause each excimer laser beam B to enter the second segment lens 25a adjacent to the one on which this laser beam B is to be incident. As a result, light leakage and thus sidebands may occur. In this case, the excimer laser beams B cannot be normally condensed on the glass substrate 4. The excimer laser beams B may thus be tilted.

This means that the substantial beam width of each excimer laser beam B decreases. Then, in an extreme case, the beam width of the excimer laser beam B decreases down to about 200 μm. As a result, the number of times each point on the glass substrate 4 is irradiated with the laser beam decreases to about 10. This reduces the fluence margin on the glass substrate 4.

Thus, by, for example, setting the radius of curvature r of each first segment lens 24a of the first short axis homogenizer 24 to 219 and setting the focal distance f of the first segment lens 24a to 438, it is possible to reduce the beam diameter of each excimer laser beam B on the second segment lenses 25a of the second short axis homogenizer 25 down to 0.1 mm, as shown in FIG. 3.

A reduction in substantial beam width can be prevented by setting the span between the first segment lens 24a and the corresponding second segment lens 25a to 460 mm. However, unless the orientations of the excimer laser beams are corrected, the excimer laser beams B are not normally incident on the corresponding second segment lenses 25a of the second short axis homogenizer 25. Consequently, the substantial fluence on the glass substrate decreases down to a level insufficient for production.

Furthermore, it is possible to determine whether or not each excimer laser beam B is incident on the first short axis homogenizer 24 at the appropriate angle, by selecting the plurality of angles of the first mirror 13, installed closer to the laser oscillator 11 than the first short axis homogenizer 24, and using the beam profiler 35 to measure the shape of the excimer laser beam B at each of the selected plurality of angles.

Specifically, a micro actuator installed at the first mirror 13 is used to remotely control the angle of the first mirror 13 to select the plurality of angles of the first mirror 13. Then, the profiler 35 is used to measure the beam shape of each excimer laser beam B at each of the selected angles of the first mirror 13. Then, within the results of the measurements of the beam shape executed by the beam profiler 35, the angle of the first mirror 13 at which the excimer laser beam B has the maximum intensity in each of the long axis direction and short axis direction is selected as the optimum condition and adjusted.

In other words, within the results of the measurements of the beam shape executed by the beam profiler 35, the angle of the first mirror 13 at which an intensity distribution curve obtained by drawing the beam profile of the excimer laser beam B along at least one of the long and short axis directions has the largest height is selected as the optimum condition and adjusted.

In this case, the orientation of the excimer laser beam B can be accurately corrected by setting the laser oscillation frequency used during the measurements by the beam profiler 35 equal to that of the excimer laser beam B required for conversion into the polysilicon layer 2.

This operation enables the maximization of the beam width and fluence margin of the excimer laser beam B on the glass substrate 4. In other words, the value of the fluence F2 can be increased to enable the intensity of each excimer laser beam B to be properly adjusted all over the surface of the glass substrate 4. Thus, when incident on the glass substrate 4, the excimer laser beams B are sufficient to convert the amorphous silicon layer into the polysilicon layer 2.

It is thus possible to manufacture at a excellent productivity and a very high yield, a large amount of uniform, high-performance thin film transistors 3 exhibiting a high mobility all over the surface of the glass substrate 4 and having uniform characteristics. Thus, a large amount of high-quality low-temperature polysilicon liquid crystal displays can be produced. This makes it possible to put a large amount of low-temperature polysilicon liquid crystal displays, which are conventionally difficult to mass-produce, to practical use at a high yield with reduced costs.

In the above embodiment, the laser oscillation frequency used when the beam profiler 35 is used to measure the beam shapes is set equal to that of the excimer laser beams B for laser annealing. However, if the beam profiler 35 can carry out checks by measuring the beam shapes only at a laser beam frequency lower than that for laser annealing, even if the beam shapes are measured at the maximum laser oscillation frequency at which the beam profiler 35 can achieve measurements through oscillations, the angles at which each excimer laser beam B is incident on the first short axis homogenizer 24 and second short axis homogenizer 25 only slightly deviate from its optimum values. Consequently, the manufacture of the thin film transistor 3 is rarely affected. Therefore, this method provides operations and effects similar to those of the above embodiment.

Furthermore, the description of the above embodiment relates to the laser irradiation apparatus as a laser anneal apparatus which irradiates the amorphous silicon on the glass substrate 4 with the excimer laser beams B to convert the amorphous silicon into the polysilicon layer 2. However, the laser irradiation apparatus can also be used to activate a film such as amorphous silicon on the glass substrate 4 to covert it into the channel region 46 or the like.

As described above, according to the present invention, the intensity of each laser beam can be properly adjusted all over the translucent substrate by adjusting the angle of the mirror to cause the short axis homogenizers to adjust the short axis-wise width of each laser beam and thus its intensity and then irradiating the amorphous silicon semiconductor on the translucent substrate with the laser beams.

1. A method of laser irradiation comprising:
reflecting a laser beam from a mirror to bend an optical path of the laser beam;
adjusting a width of the laser beam in the short axis direction of the laser beam whose optical path is bent by the mirror, by first and second short axis homogenizers each having two cylindrical lens arrays each including a plurality of segment lenses having the same radius of curvature; and
irradiating an amorphous silicon semiconductor on a translucent substrate with the laser beam whose width in the short axis direction is adjusted by the first and second short axis homogenizers,
wherein each segment lens of the first short axis homogenizer condenses the corresponding laser beam substantially on a center of the opposite second short axis homogenizer in the first and second short axis homogenizers, a plurality of angles of the mirror are selected, the shape of each laser beam at each of the selected plurality of angles measured using a beam profiler, and the intensity of the laser beam is adjusted, within results of the measurements, as an optimum condition, by adjusting the angle of the mirror at which an intensity distribution curve along at least one of a long and short axis directions has the largest height.

2. A method of laser irradiation comprising:
reflecting a laser beam from a mirror to bend an optical path of the laser beam;
adjusting a width of the laser beam in the short axis direction of the laser beam whose optical path is bent by the mirror, by first and second short axis homogenizers each having two cylindrical lens arrays each including a plurality of segment lenses having the same radius of curvature; and
irradiating an amorphous silicon semiconductor on a translucent substrate with the laser beam whose width in the short axis direction is adjusted by the first and second short axis homogenizers,
wherein each segment lens of the first short axis homogenizer condenses the corresponding laser beam substantially on a center of the opposite second short axis homogenizer in the first and second short axis homogenizers, a plurality of angles of the mirror are selected, the shape of each laser beam at each of the selected plurality of angles measured using a beam profiler, and the intensity of the laser beam is adjusted, within results of the measurements, as an optimum condition, by adjusting the angle of the mirror at which an intensity distribution curve along at least one of a long and short axis directions has the largest height, and a laser oscillation frequency used during the measurements by the beam profiler is set equal to that of the laser beams applied to the amorphous silicon semiconductor.
